(19) United States
(12) Patent Application Publication
(10) Pub. No.: US 2016/0081141 A1
(43) Pub. Date: Mar. 17, 2016

(54) MODULAR HEATER AND ASSOCIATED PARTS

(71) Applicant: Arsalan Emami, Aliso Viejo, CA (US)

(72) Inventor: Arsalan Emami, Aliso Viejo, CA (US)

(21) Appl. No.: 14/948,373

(22) Filed: Nov. 22, 2015

Related U.S. Application Data
(63) Continuation of application No. 13/602,346, filed on Sep. 4, 2012.
(60) Provisional application No. 62/083,300, filed on Nov. 23, 2014.

(51) Int. Cl. H05B 3/46; H05B 1/02; H05B 3/08; H01L 21/67

(52) U.S. Cl. CPC H05B 3/46; H01L 21/67109; H05B 1/0233; H05B 3/08

(57) ABSTRACT

A modular heater is disclosed, including multiple heater modules. The heater modules can include mating features, such as a tongue and groove seal, and/or soft seal, to prevent radiation, thermal convection and thermal conduction leakage. The heater module can also include heater elements, together with supports and expansion room for the heater elements as well as an ingenious heater structure and jumper and connector design for the disparate heating elements.

### FIELD OF TECHNOLOGY

This disclosure relates generally to the manufacturing of semiconductor devices and specifically the manufacturing of semiconductor devices in a furnace. The present invention includes structures for processing wafers such as structures for heating including an ingenious heater structure and heating element arrangement and parts. In one example embodiment to methods, apparatus, and systems to heat objects or workpieces such as wafers with an improved manner and design.

### BACKGROUND

This application is a continuation in part of US Patent Application 2013/0058372. The current application is an improvement design over the heater as disclosed in 2013/0058372.

Parent application, US Patent Application 2013/0058372, discloses a furnace in the aide of manufacturing substrates. Many process steps in the manufacturing of semiconductor devices are performed in a furnace. The furnace system can include a wafer loading assembly for transferring wafers to and from the furnace. Process gases can be introduced to the furnace for processing. A furnace can include a quartz tube, forming the furnace processing chamber. Heating elements can be provided on the outside the quartz tube. Heating insulation can be used to cover the heating elements, insulating the high temperature furnace processing chamber from the room temperature outside ambient. The heating insulation can minimize heat loss, resulting in higher heating temperature and faster ramp up rate for the furnace. As well as this, in general, heating elements are more efficient and resilient if thicker and more design manageable if parallel to the surface which they are mounted our planar to. This presents a design challenge and the present invention is ingenious in solving this. The present invention as founded in 2013/0058372 includes a modular heater, and a furnace utilizing the modular heater assembly that can include multiple heater modules. The modules may be of a lay down or horizontal configuration or a preferred embodiment of a vertical style. In some embodiments the heater modules can be circular in nature on the exterior, with multiple intervening layers that may include insulation layers, mechanical layers, or other layers of which provide any purpose. The interior façade of which is adjacent to the recess area may be of a circular design as in the parent application, but of which may be of an improved designed in the current embodiment as later discussed.

The heater modules can include mating features, such as a tongue and groove seal, and/or soft seal, to prevent radiation, thermal convection and thermal conduction leakage. In some embodiments, the heater module can include heater elements coupled to an insulation layer. The heater elements can be placed on the insulation layer, or can be placed in a recess area of the insulation layer. Supports for the heater elements, together with expansion room for the heater elements can be included.

### SUMMARY

Disclosed are methods, apparatus, and systems that provide a furnace and associated structure for the manufacturing of wafers or semiconductors. This application is a continuation in part of US Patent Application 2013/0058372. The current application is an improvement design over the heater as design in 2013/0058372 and includes numerous features in addition to those found in 2013/0058372.

The present invention may include additional features to the parent invention. The major improvements include a polygonal interior facade which provides further functions in design and longevity for the heating elements as found in the furnace, as well as an ingenious jumper or connector between the disparate heating elements within the furnace. These jumpers, of which may be welded and be made of multiple pieces of material may provide additional longevity and features to the furnace through multiple design and structural aspects.

The heater may comprise multiple heating elements, of which may be serpentine as found in the parent application and may be positioned within the interior recess of the furnace. Within the present embodiment the serpentine heating elements may be of disparate portions parallel, planar or alongside each interior section of the polygonal furnace interior façade and may include one or more jumpers to connect the disparate heating element parts at a respective corner or end point. Also, there may be one, two or more end connectors connected to the heating element which provide an electricity source connection of which may be external or internal to the furnace and of which may allow the elements to, with the connections, elements, and jumpers form a loop.

The methods and systems disclosed herein may be implemented in any means for achieving various aspects. Other features will be apparent from the accompanying drawings and from the detailed description that follows.

### BRIEF DESCRIPTION OF THE DRAWINGS

Example embodiments are illustrated by way of example and are not limited to the figures of the accompanying drawings, in which, like references indicate similar elements.

FIG. 1a is a perspective view of the present invention heating furnace in a prior embodiment notably with a circular interior facade.

FIG. 1b is a blown-up perspective view of the present invention heating furnace in a prior embodiment notably with a circular interior facade.

FIG. 2 is a blown-up perspective view of the present invention heating furnace in a prior embodiment.

FIG. 3a is a perspective view of an embodiment of the present invention heating furnace notably with polygonal interior façade.

FIG. 3b is a top-down view of an embodiment of the present invention heating furnace notably with polygonal interior façade.

FIG. 4a is a diagram and associated current diagram of a prior embodiment.

FIG. 4b is a diagram and associated current diagram of a prior embodiment.

FIG. 5a is a parts view of elements of an embodiment of the present invention heating furnace.

FIG. 5b is a parts view of elements of an additional embodiment of the present invention heating furnace.

FIG. 5c is a parts view of elements of an additional embodiment of the present invention heating furnace.

FIG. 6a is a limited perspective view of an embodiment of the jumper element of the present invention heating furnace.

FIG. 6b is a limited perspective view of an embodiment of the jumper element of the present invention heating furnace.

FIG. 6c is a limited perspective view of an embodiment of the jumper element of the present invention heating furnace.

FIG. 7a is a diagram and associated current diagram of an embodiment of the present invention heating furnace.

FIG. 7b is a diagram and associated current diagram of an embodiment of the present invention heating furnace.

FIG. 8a is a limited perspective parts view of an embodiment of the jumper connections the present invention heating furnace.

FIG. 8b is a diagram and associated current diagram of an embodiment of the present invention heating furnace.

FIG. 8c is a diagram and associated current diagram of an embodiment of the present invention heating furnace.

FIG. 9 is a procedure diagram for welding an embodiment of the jumpers of the present invention heating furnace.

FIG. 10 is an additional procedure diagram for an embodiment of the jumpers of the present invention heating furnace.

FIG. 11 is an additional procedure diagram for an embodiment of the jumpers of the present invention heating furnace.

FIG. 12 is an additional procedure diagram for an embodiment of the jumpers of the present invention heating furnace.

Other features of the present embodiments will be apparent from the accompanying drawings and from the detailed description that follows.

### DETAILED DESCRIPTION

The present invention is an improved embodiment of the invention disclosed within the Parent application, US Patent Application 2013/0058372 and as mentioned previously.

In the present invention two main improvements have been added. The first is the ingenious polygonal interior façade for the disparate heating elements to be planar or parallel to. The second is the ingenious jumper connector for the disparate heating elements.

Polygonal Interior

In continuing practice, the applicant has found that in certain circumstances, thicker and larger heating elements become necessary. Thicker and larger heating elements, due to space restraints and design constraints, especially considering the preferred serpentine pattern, have preferred orientation to the interior recess. With this, the circular design of the interior of the furnace, may not suffice for the heating elements as the circular nature may provide difficulty in positioning the fitting the larger heating elements. It then becomes apparent that the heating elements being planar to the interior façade layer may be necessary. As such, a polygonal structure of the interior façade, ingeniously provides for a constantly planar surface for the heating elements to be structured or connected to. In the present invention then, the interior of the heater assembly, may be of any shape such as a polygonal shape or structure. In past embodiments, the interior was seen to be as continuation of a circular structure, but in an improved apparatus, the interior may be of a polygonal structure.

In some embodiments, in addition or in combination with other embodiments, of which may also be described in 2013/0058372, the furnace includes an interior recess.

In some embodiments, in addition or in combination with other embodiments, of which may also be described in 2013/0058372, the furnace includes an interior recess with a circular structure or circular façade.

In some embodiments, in addition or in combination with other embodiments, of which may also be described in 2013/0058372, the interior façade of the heater assembly, namely the surface adjacent to the interior recess of the heater or furnace, in a preferred embodiment may be the insulating layer, and of which may provide structure and design to support or house the heating elements for the furnace.

In some embodiments, in addition or in combination with other embodiments, the furnace includes an interior recess with a polygonal structure or polygonal façade on the interior of the façade layer of the furnace or heater.

In some embodiments, in addition or in combination with other embodiments, the present invention may provide a structure or layer of which may be the layer adjacent or in contact with the interior recess, or may incorporate multiple layers for façade of which may be polygonal in nature and design and of which may permeate the polygonal design through multiple layers, or be designed to allow for the remainder of the layers to the exterior to be circular, with solely the interior façade layer to be polygonal.

In some embodiments, in addition or in combination with other embodiments, the polygonal interior is an improvement wherein it improves a function for the heating elements or strips.

In some embodiments, in addition or in combination with other embodiments, the heating elements for various reasons, such as a necessity for a thicker element design, necessitates or is preferred to be parallel or planar towards the façade of the structure slayers and exterior layer, as such a polygonal interior façade or layers, allows the heating strips to be parallel or planar to the aforementioned interior faced or layer.

Jumpers or Connectors

In the invention found within 2013/0058372, connections between the heating elements were done either through a weld or pressure contact. However due to the nature and design of the weld in the previous arts as aforementioned, the weld structure and orientation are somewhat prone to degradation, as such an improved jumper, accommodating the polygonal interior, as well as a better weld and connector structure are explained.

In some embodiments, in addition or in combination with other embodiments the heating elements are disparate or disconnected.

In some embodiments, in addition or in combination with other embodiments the heating elements are disparate or disconnected due to design restraints such as being displayed across angular structures, such as a corner of the polygonal façade.

In some embodiments, in addition or in combination with other embodiments, the disparate heating elements are connected.

In some embodiments, in addition or in combination with other embodiments, the disparate heating elements are connected by jumpers or connectors.

In some embodiments, in addition or in combination with other embodiments, the disparate heating elements are connected by jumpers or connectors of any angle or length.

In some embodiments, in addition or in combination with other embodiments, the jumpers comprise two strips, wherein the two strips are configured to form two ends.

In some embodiments, in addition or in combination with other embodiments, the each end of the two strips comprises two substantially parallel surfaces facing each other where each end of the two strips is configured to enclose an heating elements with two substantially parallel surfaces pressing on two sides of the heating elements and of which a weld element connects the two strips.

In some embodiments, in addition or in combination with other embodiments, the jumpers, connector, heating elements, strips or jumpers may be comprised of one material.

In some embodiments, in addition or in combination with other embodiments, the jumpers, connector and heating elements may be comprised of more than one or a composite of materials.

In some embodiments, in addition or in combination with other embodiments, the jumpers, connector and heating elements may be comprised of any material in any combination orientation or state.

In some embodiments, in addition or in combination with other embodiments, the jumpers, connector and heating elements may be comprised of a metallic material or an alloy material.

In some embodiments, in addition or in combination with other embodiments, the jumpers, connector and heating elements may comprise of an alloy comprising of iron, chromium and aluminum

In some embodiments, in addition or in combination with other embodiments, the jumpers, connector and heating elements may comprise of an alloy comprising of NiFe, NiCr, CuNi, MoSi2, and SiC.

In some embodiments, in addition or in combination with other embodiments, the jumpers, connector and heating elements may comprise of Kanthal or FeCrAl.

The connector or jumpers comprised of heating elements may be made of an alloy that is stable in hot air, cold air or at any temperature.

In some embodiments the jumper or connector may be manufactured of made with a weld element to connect the disparate internal and external parts of the jumper

In some embodiments, in addition or in combination with other embodiments, the weld element may comprise similar or the same materials as the heating elements

In some embodiments, in addition or in combination with other embodiments, the weld element may be configured so that the two strips press on the heating elements

In some embodiments, in addition or in combination with other embodiments, the weld elements may be at one side or both sides of the strips.

In some embodiments, in addition or in combination with other embodiments, there may be additional material compressing on the heating elements.

In some embodiments, in addition or in combination with other embodiments, a “jumper” made of a similar material or dissimilar material to the heating strips may be constructed to join two or more disparate heating elements at a junction, corner or for other reasons. These jumpers, which may be made of the same material as the heating elements, or of a different material help the heating strips both fit into the structures well as improve efficiency and longevity.

In some embodiments, in addition or in combination with other embodiments, the jumpers may connect a series of heating elements together in line.

In some embodiments, in addition or in combination with other embodiments, the jumpers may connect a series of heating elements to follow the circumference or perimeter of the interior of the heater's facade

In some embodiments, in addition or in combination with other embodiments, the jumpers may be made of multiple pieces and may be of a welded design and may take the form of any angle or structure, whether thicker or thinner than the heating strips.

In some embodiments, in addition or in combination with other embodiments, the heating element ends are disparate in respect to each other at an angle which is an integer fraction of 360 degrees.

In some embodiments, in addition or in combination with other embodiments, the angles between each disparate heating element is the same.

In some embodiments, in addition or in combination with other embodiments, the angles between the disparate heating elements is the same.

In some embodiments, in addition or in combination with other embodiments, the angles between some disparate heating elements are the same while others are different.

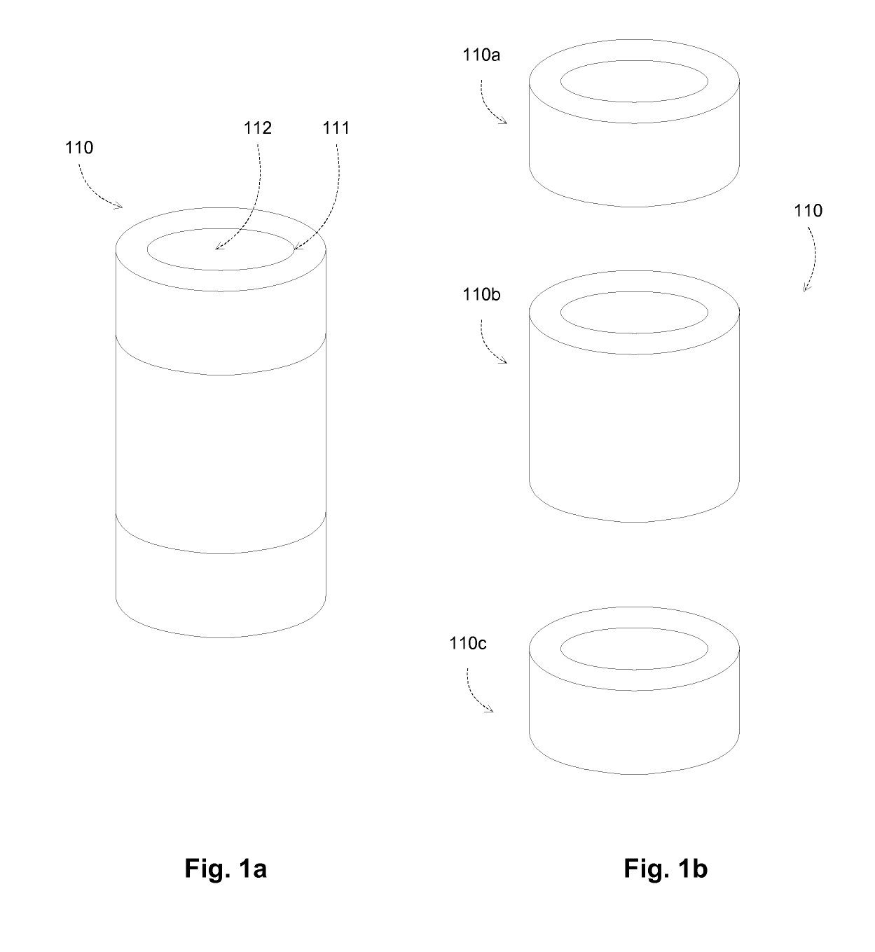

FIG. 1a displays the previous embodiment modular heating assembly 110 as found in 2013/0058372. It is noted that the interior façade 111 and recess 112 may be of a circular structure of which the non-pictured heating elements are displayed on.

FIG. 1b displays the previous embodiment modular heating assembly 110 as found in 2013/0058372, of which can include the modularity as demonstrated in FIG. 1b wherein the heater can be broken into module 110a, 110b and 110c as well as numerous other features.

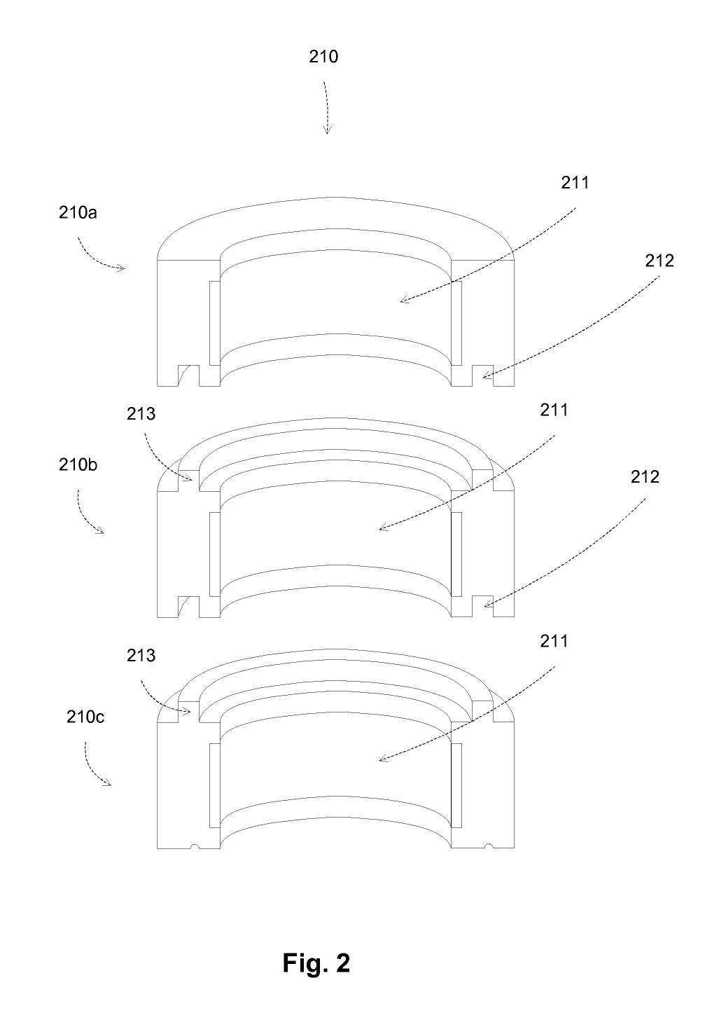

FIG. 2 displays the previous embodiment modular heating assembly 210 as found in 2013/0058372 of which may provide a modular design including modules 210a, 210b and 210c and of which may include layers, such as an insulation layer 211 as well as coupling designs such as recess 212 and extrusion 213 which may help with many features such as reducing heat transfer out of the interior recess of the furnace as described in 2013/0058372.

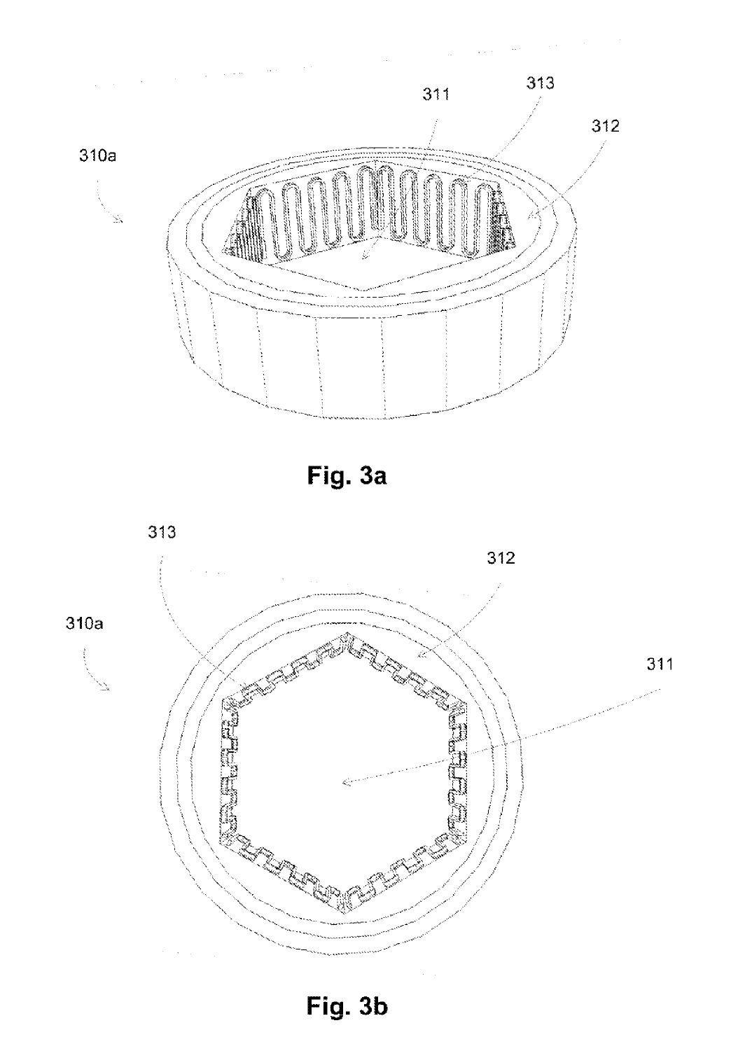

FIG. 3a provides a perspective view of a present embodiment displaying the polygonal interior recess 311 and polygonal interior layer 312. The interior polygonal interior layer 312 then provides a planar surface for the heating elements 313 to be mounted upon. It is noted that the heating elements are disparate and serpentine as is described in a preferred embodiment, but also can be of other orientations and designs.

FIG. 3b provides a top-down view of the present embodiment displaying the polygonal displaying the polygonal interior recess 311 and polygonal interior layer 312. The interior polygonal interior layer 312 then provides a planar surface for the heating elements 313 to be mounted upon.

Jumpers or Connectors

In some embodiments, namely with the polygonal interior design but also with circular interior designs, the heating element, instead of being continuously radial through the circumference of the interior of the heater, may be disparate and thus may have connection area where two or more respective parts of the heating strip are at offset angles. At these points, having a continuous strip either are not possible and thus are disconnected or also may be possible by bending or having the heating elements formed to form the corner structure. However, a continuous connection may provide a dis-benefit as due to the interior design and thickness of the heating elements, a continuous structure may not fit, and also a bending the structure may weaken the heating elements.

In terms of the connections between the disparate heating elements or strip, the least resistance design is the most efficient and sought after. Resistance in the connection leads both to inefficiency, as well as excess heat which degrades the connection as well as degrades the integrity of the heating strips.

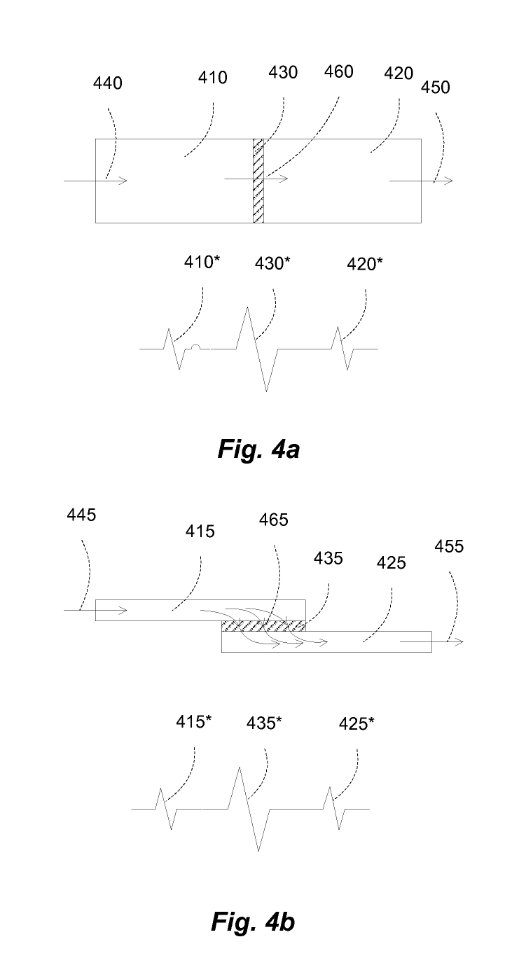

FIG. 4a shows an embodiment of the prior embodiments found in 2013/0058372 wherein 420 is one heating element and 420 is another heating element, or the next element down the current path. A current may flow across the heating element from 440 to 450 over respective element 410 and 420. The two heating elements are connecting by a weld 430. The associated current diagram shows the resistance as the current 440 flows to 450. While the current flows through the heating element 410, a normalized resistance is seen through 410* such as 1 Ohm, as the current flows through the weld connection 430, the resistance is shown by 430* such as 10 Ohms and as the current flows through the heating element 420, the normalized resistance is shown by 420* such as 1 Ohm. It is of purpose and note that the resistance spikes considerably as the current travels through the weld, of which is inefficient and undesirable.

FIG. 4b shows a different prior embodiment and arrangement as found in 2013/0058372. FIG. 4b which is a differently oriented connection but uses the same connection point for the heating elects. The current 445 travels through the heating element 415 which is connected by weld 435 to heating element 425 of which then the current 455 travels out. The current while traveling through the heating element 415 is seen to have a resistance of 415* such as 1 Ohm, as the current 465 travels throughout the weld 435, it has a resistance 435* such as 10 Ohms and as the current travels through the heating elements 425, has a resistance 425* such as such as 1 Ohm. It is again noted the resistance throughout the weld 465 is higher than traveling through heating elements 415 and 425.

With this, FIGS. 4a and 4b demonstrate that resistance through the weld are higher than in the associated heating elements, and as such are a localized point of failure and inefficiency. It is noted that the current embodiment improves on this. Also typical weld materials 430 can have lower melting temperature than metals 410 and 420 and as such for high current applications, the weld can fail (e.g., melt) first, if material selection is not proper. Also, typical weld materials 430 can be different from metals 410, 420. Which can lead to difference in thermal expansion, so for high current applications, the weld can fail first due to stress and strain related to thermal expansion mismatch, if material selection is not proper

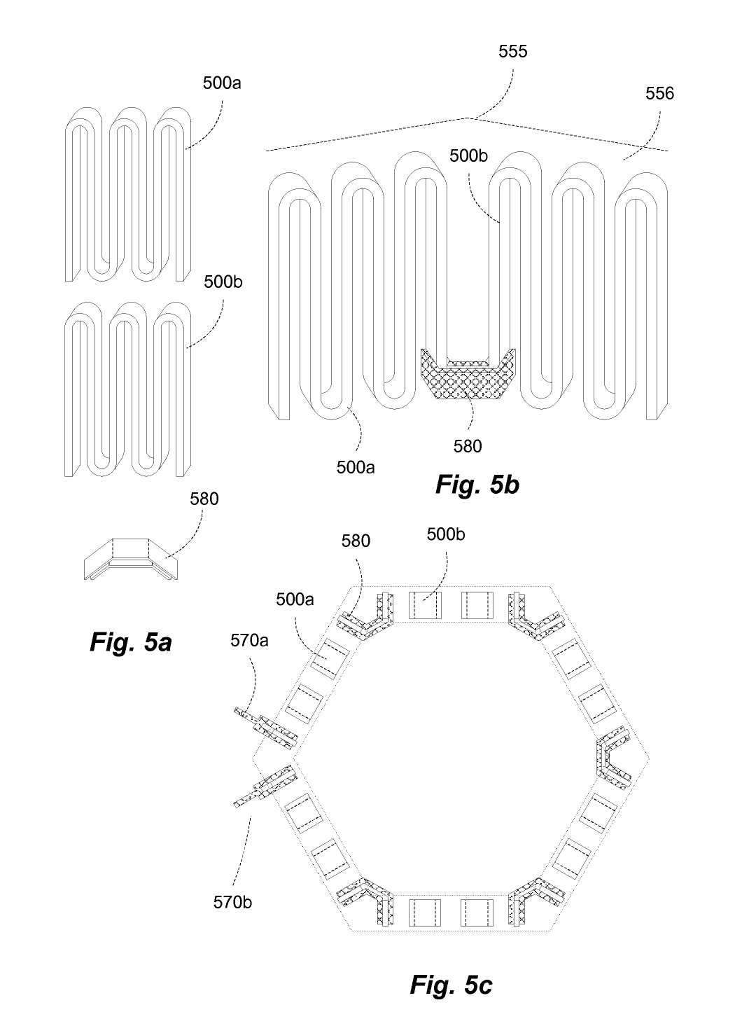

FIG. 5a teaches towards the serpentine heating elements as found in the parent application and the current continuation. This includes a first heating element 500a and second heating element 500b. Also included disparity is the present jumper 580 of which may be used to connect 500a and 500b.

FIG. 5b demonstrates the above mentioned pieces as found in FIG. 5a, in their installed state in a current embodiment, including first part of the heating element 500a, second heating element 500b, and jumper 580 which connects the first heating element 500a and second heating element 500b of which it is noted at the angle 555 existing due to the polygonal formation of the interior recess of the heater 556.

FIG. 5c is a top down view showing the arrangement of the heating elements, jumpers, and connections, with first heating element 500a being positioned with jumper 580 providing an angle connection to second heating element 500b. It is noted that the arrangement may provide a closed loop or follow the entirety of the circumference or length of the interior of the furnace or interior recess. Also, some of the jumpers may provide to a connection to the exterior of the furnace such as connectors 570a and 570b, which may not provide an interior jump connection from heating element to heating element, but may provide a connection to the exterior or interior of the furnace for a source of electricity or other use. It is noted that in an embodiment, a current may be provided into the heating furnace from an exterior source or interior source into connection 570a, may travel from 570a through intermediary heating elements, such as 500a, and 500b, which may be connected via jumpers or connectors 580, around the entirety of the interior of the furnace of which may be arranged with a polygonal façade along with the heating elements and jumpers, and complete a circuit to the said power source through a connection 570b of which may extrude to the exterior of the furnace or connect to a power device in the interior of the furnace. Connector 570a and 570b may be connection to a heating element in the same fashion as the jumpers, or in a different fashion and may be made of any material, the same or different and of any permeation or number of materials, and also may extrude out of the furnace to any layer of the furnace and may connect or provide for any type of function such as being connected to an electricity source as is found in the previous application.

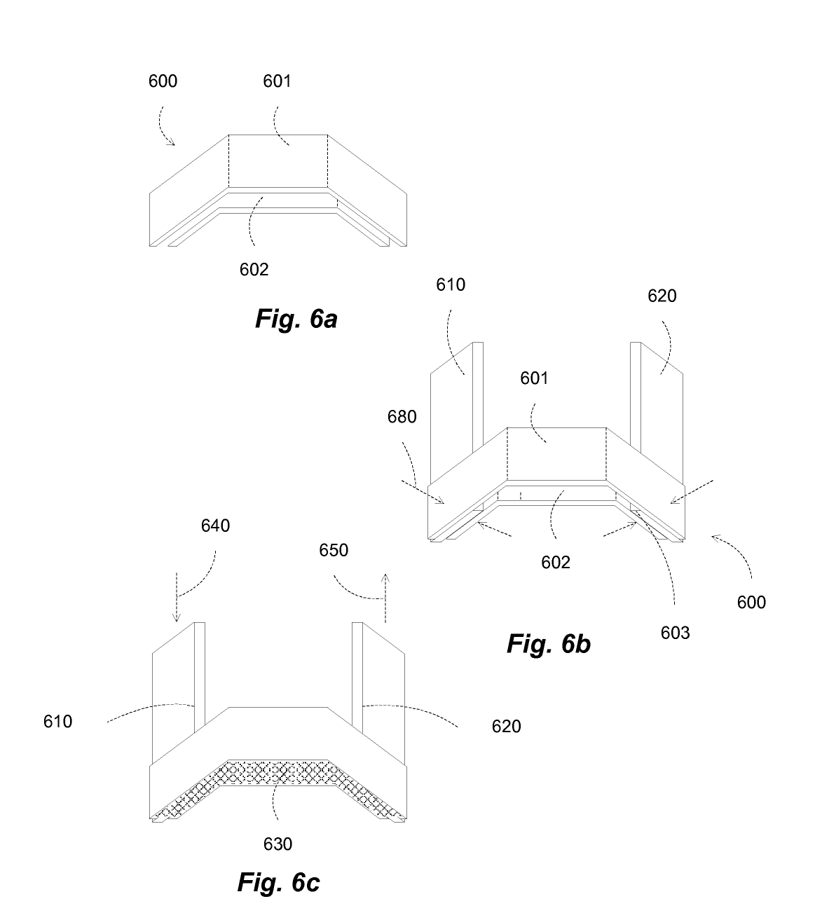

FIG. 6a teaches to an embodiment of the jumper 600 with one part 601 and second part 602, of which a recess 603 exists between the parts 601 and 602. And of which the parts may be structured in an angled portion to fit to fit together to form a uniform interior recess 602. The design of the preferred embodiment and structures as displayed of 600 may be of any structure or angles, as necessitated by the heating elements, and heater structures.

FIG. 6b teaches to an embodiment of the jumper 600 with one part 601 and second part 602, of which a recess 603 exists between the parts 601 and 602 and of which disparate heating element 610 and disparate heating element 620 may be position between part one of the jumper 601 and part two of the jumper 602 at differing ends of the jumper, and of which a force, such as a clamping force 680 may constrict the heating elements parts 610 and 620 between the jumper parts 601 and 602.

FIG. 6c teaches to an embodiment of the jumper like 6a and 6b, wherein a weld material 630 may be enlisted to weld the all or some of the parts of the jumper and heating element together for any purpose or use, such as to reduce resistance, provide longevity, or keep the parts together. Soldering or other types of connection, such as friction fit, molded fit, or others may be used. Also, any type of material may be used, of which may be the same material as the heating element or jumper, or of a different material. The welding may take place while pressure 680 in FIG. 6b is enlisted providing for a more complete weld or contact are. Also a current 640 is displaced to enter the jumper through heating element 610 and exit the jumper as current 650 to continue in the second heating element 620.

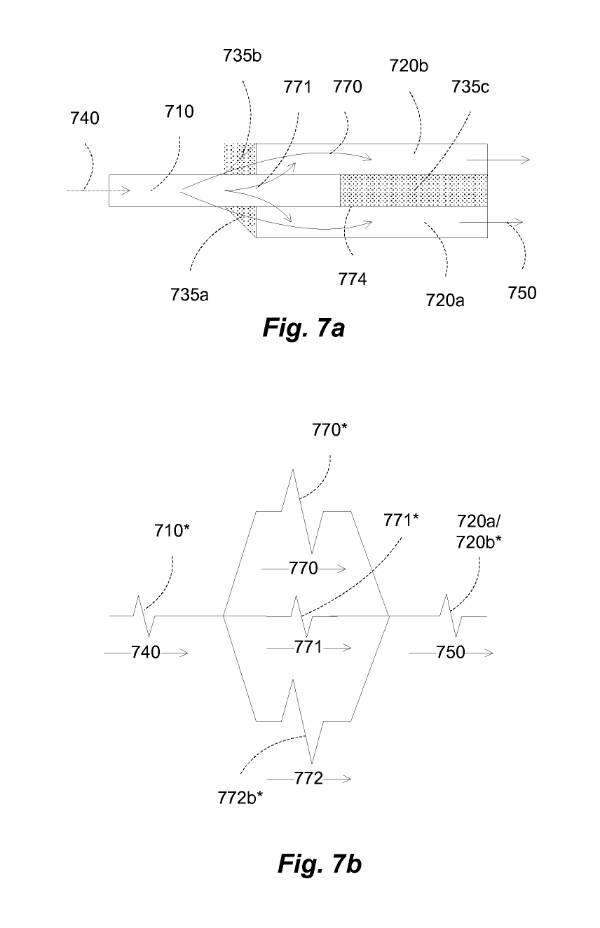

FIG. 7a teaches towards a cross section of the connection between the heating element 710 and the first jumper piece 720a and second jumper piece 720b. Pieces 720a and 720b may be held together in any form as previously mentioned and may also include weld sections 735a, 735b and 735c of which may also may provide a route for a current 770 to pass. Current 740 can run through the heating element 810, pass through the weld 735a or 735b, via current vector 770 or pass through by direct contact between the heating element and jumper via current vector 771. The current can then travel down each piece of the jumper 720a or 720b to a destination in current vector 750 of which may then travel to the next heating element or connector. Weld 735c can aid in this current vector, as well as provide structural material to aide in other uses such as heat management, strength etc.

FIG. 7b teaches towards a current diagram for the above 7a embodiment. This concludes the current 740 running within the heating element and having a resistance 710*. At the connection between the welds 735a and 735b, and the jumper 710 connecting either through direct contact or through the welds to jumper pieces 720a and 720b, it is seen that there are multiple vectors currents such as 770, 771 and 772 with resistances 770*, 771* and 772*. It is noted that with multiple paths with varying resistance, the total resistance for a given current becomes less than if just one vector existed, as found in the previous embodiments in FIG. 4. This embodiment and configuration allows for the welds to be larger and have more area than the previous embodiments, and allows for an improvement over the past configuration with a much lower resistance and as such since weld area is larger and more direct contact exists, the heating at weld area is proportionally less. Also it is possible that the resistance at the connect between heating element 710 and jumper pieces 720a and 720b is smaller than the resistance at the interim connection welds 735a and 735b, and as such because the resistance is less at the direct contact points, the majority of the current will travel between the element and the jumper through the direct contact point and not the welds, lessening the heat buildup in the welds, and thus providing better efficiency and integrity.

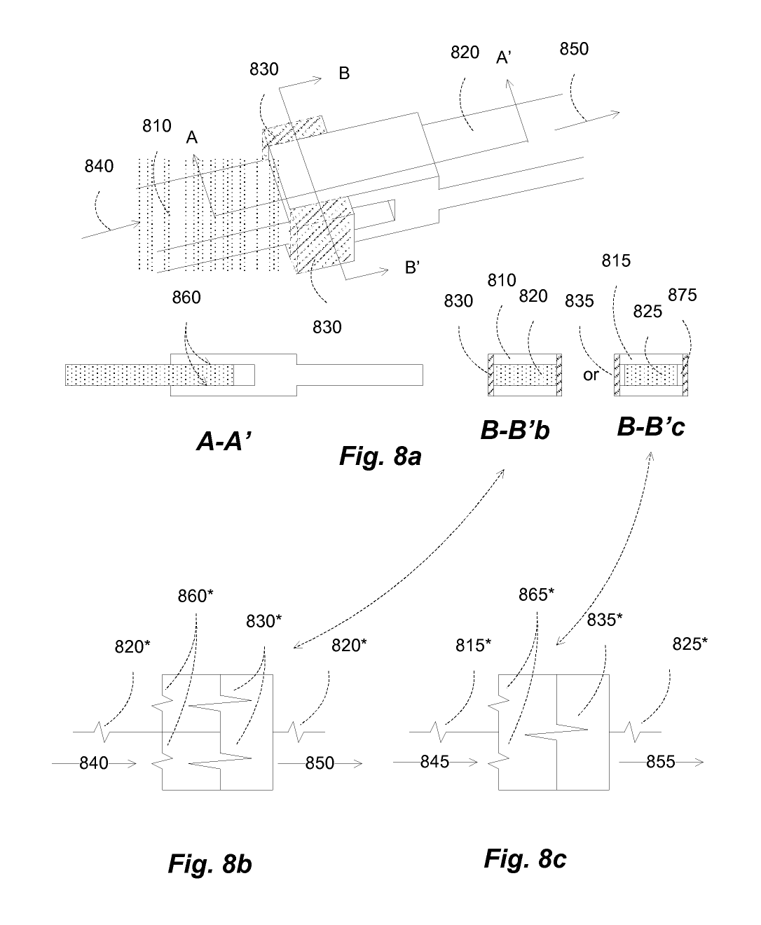

FIG. 8a teaches towards an additional embodiment press contact weld at locations with low or no current passing through the weld. The configuration entails a press contact two sides of an end of the metal of which are welded together at two sides. The weld can be used to keep the pressure on the contact and are created by press two sides of one end of a metal bar to one end of another metal bar and welding the two sides together while keeping pressure on the two sides. A current 840 may travel down the heating element 810 and subsequently travel through the weld 830 and into the jumper 820 as current 850. In sight line A-A′ it is noted that the 810 heating element is press fit into the interior of the jumper 820 with direct contact better the jumper and heating element at 860 of which the current may directly flow. It is noted that in sightline B-B′b a weld 830 provides a structural support to connect the press fit heating element 820 and jumper 810 of which have direct contact and through the weld 830. In another embodiment B-B′c it is also noted that the weld 835 can have no direct contact with the heating element 825, providing just a structure for the jumper 815, which houses an extrusion of the heating element in its recess, with a press fit, and of which has direct contact between the heating element 825 and jumper 815 for current to pass through. In this embodiment, because the weld does not contact the heating element and jumper with a gap 875 current will not flow across the weld, and as such the weld will become structurally sounds as it will not be degraded by heat and other characteristics of carrying a current.

FIG. 8b teaches towards the current diagram for embodiment B-B′b as mentioned above in FIG. 8a. It provides a current 840 with resistance 810* traveling through the heating element 810. The current than travels through direct contact to the jumper 810 at direct contact points with resistance 860* or also through the welds 830 with a resistance 830*, of which then the current travels through the jumper onwards with current 850 and resistance 820*. It is noted that with the multiple paths of current and namely the larger direct contact area between the jumper and the heating elements, the total resistance to the current is less than previous embodiments, of which will provide a more efficient and resistant structure. Also, it is noted that the resistance will be higher in the welds than the direct contact so a majority of the current will travel via direct contact between the heating element and the jumper and as such the jumpers will have an increased longevity as well as other positive features.

FIG. 8c teaches towards the current diagram for embodiment B-B′c as mentioned above in FIG. 8a. It provides a current 845 with resistance 815* traveling through the heating element 810. The current than travels through direct contact to the jumper 810 at direct contact points with resistance 865*. In this embodiment, because the welds do not contact the heating strip with a gap 875, and very large resistance as a function of the air or gas or environment in-between the heating element and jumper, of which the current would have to jump is extremely high at 835*. The current then would travel through the jumper onwards with current 850 and resistance 820*. It is noted that with the multiple paths of current and namely the larger direct contact area between the jumper and the heating elements, the total resistance to the current is less than previous embodiments, of which will provide a more efficient and resistant structure. Also, it is noted that due to no direct contact between the jumper and heating elements, and the thus extremely large resistance for the jump between the two, at gap 875, the current will solely pass form the heating element to the jumper via direct contact, preserving the weld from heat and other factors for increased efficiency and longevity.

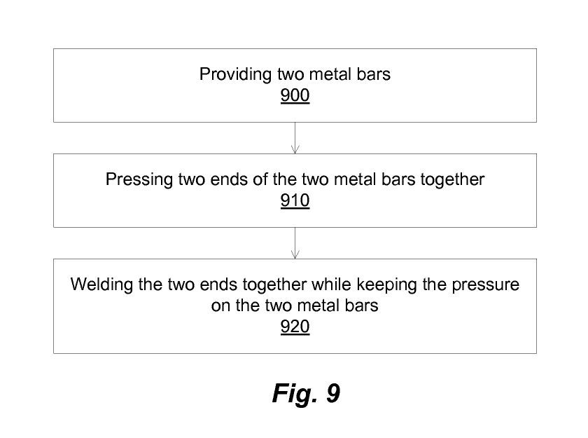

FIG. 9 teaches towards a process to align and provide for the creation of the present invention. This includes step 900 which provides two metal bars, of which may be of the same material, or different material as the respective heating element to later be attached two. Step 910 provides for pressing the end ends of the metal bars together to form a jumper. 920 provides for welding the two ends together while keeping the pressure on the metal bars to provide for a solid connection in the aim of reducing resistance or other positive aspects such as increased longevity and reduced heat.

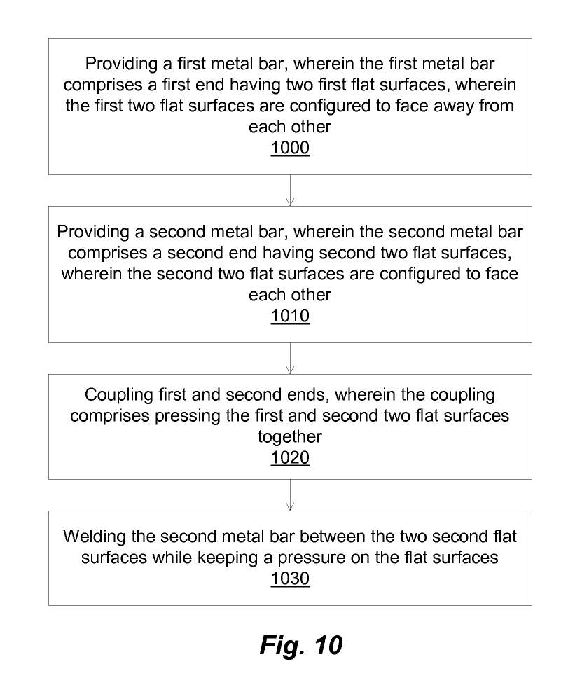

FIG. 10 provides additional steps to provide for the present invention. This includes step 1000 which provides e first metal bar piece of the jumper, and wherein the a first end having two first flat surfaces, wherein the first two flat surfaces are configured to face away from each other, Step 1010 wherein a second metal bar comprises a second end having second two flat surfaces, wherein the second two flat surfaces are configured to face each other. Step 1020 wherein coupling first and second ends, wherein the coupling comprises pressing the first and second two flat surfaces together and Step 1030 wherein welding the second metal bar between the two second flat surfaces while keeping a pressure on the flat surfaces.

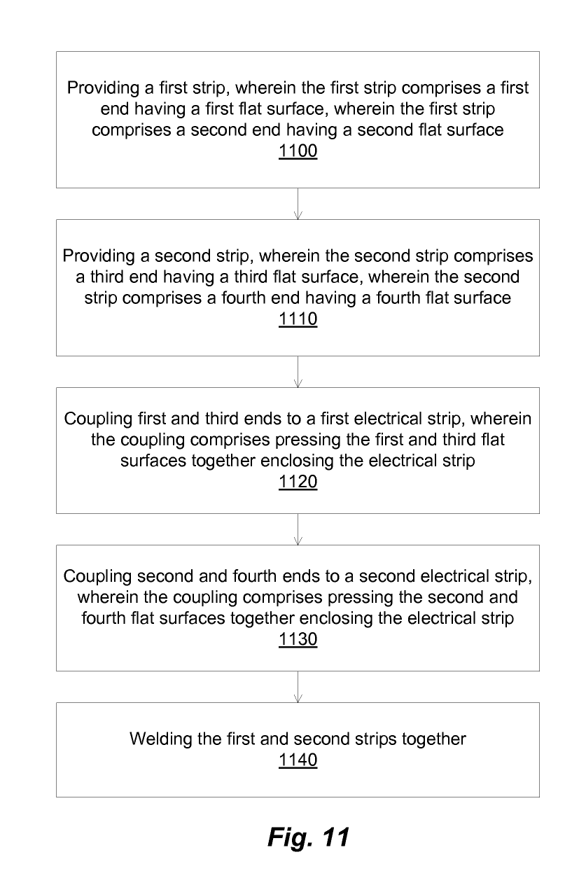

FIG. 11 teaches to additional steps to provide for the present invention wherein Step 1100 providing a first strip, wherein the first strip comprises a first end having a first flat surface, wherein the first strip comprises a second end having a second flat surface, Step 1110 providing a second strip, wherein the second strip comprises a third end having a third flat surface, wherein the second strip comprises a fourth end having a fourth flat surface, Step 1120 coupling first and third ends to a first heating element, wherein the coupling comprises pressing the first and third flat surfaces together enclosing the heating element, Step 1130 coupling second and fourth ends to a second heating element, wherein the coupling comprises pressing the second and fourth flat surfaces together enclosing the heating element and Step 1140 welding the first and second strips together

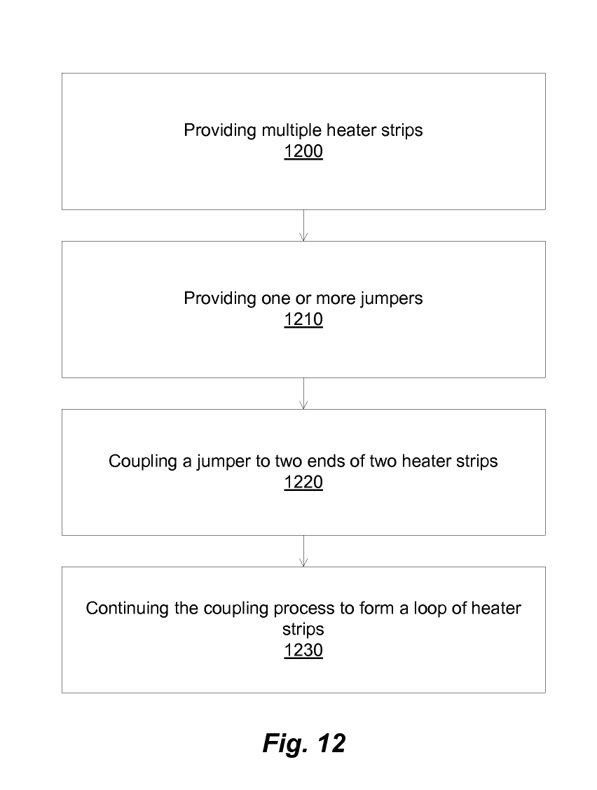

FIG. 12 provides further process to provide for the present invention including Step 1200 providing multiple heater strips, Step 1210 providing one or more jumpers, Step 1220 coupling a jumper to two ends of tow heater strips and 1230 continuing the coupling process to form a loop of heater strips.

The methods and systems disclosed herein may be implemented in any means for achieving various aspects. One notable implementation is the description of the direction of the current and the aspect of being an entry or exit of the current. It is noted that all of the connections and structures described, may be flipped in direction or orientation in terms of physical structure and use. For instance the figures describe the current traveling at the exit point of the heating element, and into the jumper. This may be flipped and provided in the same scope of the invention to be exiting the jumper and entering a heating element. It is dually noted that all connections and structures may be modified to provide for such a case, and of which is necessary in the scope of the invention. Other features will be apparent from the accompanying drawings and from the detailed description that follows.

1. A heater module comprising:
an interior recess and an interior recess façade, housing;
heating elements, wherein,
the heating elements are coupled to the first layer of the interior recess façade, and
the heating elements are disparate into one or more elements.

2. A heater module as in claim 1, wherein:
the interior recess façade is polygonal.

3. A heater module as in claim 1, wherein:
the heating elements are serpentine.

4. A heater module as in claim 1, wherein:
the heating elements are made of Kanthal (FeCrAl).

5. A heater module as in claim 1, wherein:
the disparate heating elements line the interior recess of the heater.

6. A heater module as in claim 1, wherein:
the disparate heating elements are connected by jumpers.

7. A heater module as in claim 6, wherein:
the heating elements and the jumpers are made of the same material

8. A heater module as in claim 6, wherein:
the jumpers are made of more than one part, wherein
a first part of the jumper and a second part of the jumper are structured parallel to each other, and
the first and second part are uniformly angled and positioned to form a recess between them.

9. A heater module as in claim 8, wherein:
a first heating element protrudes into the jumper recess in a first position from a vertical disposition, and
a second heating element protrudes into the jumper recess in a second position from a vertical disposition.

10. A heater module as in claim 9, wherein:
the heating element and the jumper are connected via a friction fit in the recess.

11. A heater module as in claim 9, wherein:
the heating element and the jumper are connected via a weld and a weld material.

12. A heater module as in claim 11, wherein:
the weld and weld material are the same material as the jumper or the heating element.

13. A heater module as in claim 9, wherein:
the heating element and the jumper are connected via a friction fit and a weld and a weld material, wherein;
the weld and the weld material contacts the heating element and the jumper parts as a structure and as a current carrier.

14. A heater module as in claim 13, wherein:
the resistance of the weld is greater than the contact of the jumper and heating element, wherein;
the current travels through the contact of the jumper and heating element and not the weld and weld material.

15. A heater module as in claim 9, wherein:
the weld and weld material only contact the first part of the jumper and the second part of the jumper, wherein;
the weld and the weld material do not contact the heating elements,
the heating elements directly contact the jumper parts solely, and
the heating elements are held in the recess via friction fit.

16. A method comprising:
arranging a first piece of a jumper and a second piece of a jumper parallel to form a recess,
protruding a first heating element in to the jumper recess on one side from a vertical disposition, and
protruding a second heating element into the jumper recess on one side from a vertical disposition that is in respect to the first heating element.

17. A method as in claim 16 further comprising:
impinging positive pressure on the first piece of the jumper and the second piece of the jumper wherein the first heating element and second heating element are squeezed between the first piece of the jumper and the second piece of the jumper.

18. A method as in claim 17, further comprising
creating a weld while impinging the heating element in the recess.

19. A method as in claim 18, wherein:
creating the weld as to connect the first jumper piece and second jumper piece together, wherein,
the weld does not contact the heating element, and
the heating elements are held in the recess of the first piece of the jumper and the second piece of the jumper by friction fit.

20. A method as in claim 18, wherein:
the weld and weld material connects the first jumper piece, second jumper piece and heating element together, wherein,
the weld does contact the heating element, and
the heating elements are held in the recess of the first piece of the jumper and the second piece of the jumper by friction fit and the weld.
